(19) United States
(12) Patent Application Publication
(10) Pub. No.: US 2013/0009066 A1
(43) Pub. Date: Jan. 10, 2013

(54) Block Detector With Variable Microcell Size For Optimal Light Collection

(75) Inventors: Ronald Grazioso, Knoxville, TN (US); Debora Henseler, Erlangen (DE)

(73) Assignees: SIEMENS AKTIENGESELLSCHAFT, Munchen (DE); SIEMENS MEDICAL SOLUTIONS USA, INC., Malvern, PA (US)

(21) Appl. No.: 13/539,962

(22) Filed: Jul. 2, 2012

Related U.S. Application Data
(60) Provisional application No. 61/504,816, filed on Jul. 6, 2011.

(51) Int. Cl. G01T 1/20; G01T 1/164; H01L 27/144; G01T 1/24

(52) U.S. Cl. 250/363.03; 250/366; 250/363.04; 438/73; 257/E27.127

(57) ABSTRACT

Systems, devices, and methods are provided for more efficient photon detection in nuclear medical imaging. By basing the density of photosensitive microcells in photosensors on a spatial distribution of photons across the array of photosensors, the non-linearity of the photosensors' output pulses can be reduced, and the negative effects of non-uniform distribution of light from a scintillator array can be ameliorated. As a result, the positioning and linearity information of typical photosensors used in nuclear medical imaging can be improved, and better quality images are produced.

### CROSS-REFERENCE TO RELATED APPLICATIONS

This application claims the benefit of U.S. Provisional Patent Application 61/504,816, filed on Jul. 6, 2011, the entire disclosure of which is hereby incorporated by reference.

### FIELD OF THE INVENTION

The following relates to nuclear medical imaging and more particularly to photosensors having varying microcell size and density.

### BACKGROUND OF THE INVENTION

Medical radionuclide imaging, commonly referred to as nuclear medicine, is a unique specialty wherein ionizing radiation is used to acquire images which show the function and anatomy of organs, bones or tissues of the body. The technique of acquiring nuclear medicine images entails first introducing biologically appropriate radiopharmaceuticals into the body—typically by injection, inhalation, or ingestion. These radiopharmaceuticals are attracted to specific organs, bones or tissues of interest (These exemplary organs, bones, or tissues are also more generally referred to herein using the term “objects”). Upon arriving at their specified area of interest, the radiopharmaceuticals produce gamma photon emissions which emanate from the body and are then captured by a scintillation crystal. The interaction of the gamma photons with the scintillation crystal produces flashes of light which are referred to as “events.” Events are detected by an array of photo detectors (such as photomultiplier tubes) and their spatial locations or positions are then calculated and stored. In this way, an image of the organ or tissue under study is created from detection of the distribution of the radioisotopes in the body. Known applications of nuclear medicine include: analysis of kidney function, imaging blood-flow and heart function, scanning lungs for respiratory performance, identification of gallbladder blockage, bone evaluation, determining the presence and/or spread of cancer, identification of bowel bleeding, evaluating brain activity, locating the presence of infection, and measuring thyroid function and activity. Hence, accurate detection is vital in such medical applications.

Computed tomography (CT) is a medical imaging method or modality employing tomography, i.e., imaging by sections or sectioning, created by computer processing. Digital geometry processing can be used to generate a three-dimensional image of the inside of an object from a series of two-dimensional X-ray images taken around a single axis of rotation. CT data can be manipulated to demonstrate various bodily structures based on their ability to block an X-ray beam.

Magnetic Resonance Imaging (MRI) can provide more contrast between different soft tissues than CT, making it especially useful in neurological, musculoskeletal, cardiovascular, and oncological imaging. MRI employs radio frequency (RF) fields to alter the static magnet induced magnetic alignment of the subject nuclei, for example hydrogen atoms, in the subject to produce a rotating magnetic field. This field can be detected and used to produce images of the subject.

Positron emission tomography (PET) is a nuclear medicine imaging technique or modality, which can produce a three-dimensional image of functional processes in the body, for example the functioning of an organ. In PET, a radioactive tracer radioisotope is introduced into a subject, typically by injection. The positron emitting radioisotope occurs at a higher concentration in regions of high cellular metabolic activity. When an emitted positron encounters a free electron, the positron and electron may annihilate into two gamma photons which inherently provides higher signal to noise ratio than single photon emission imaging. These gamma photons can be detected by scintillation crystals, i.e., a material that emits light upon absorbing the gamma photons. The light emitted from the scintillation crystal can then be converted to electrical charge by a photosensor, such as a photomultiplier tube (PMT) or avalanche photodiode (APD). The light sensor converts the light emitted by the scintillation crystal into a time varying stream of charge, i.e. an exponentially decaying current with decay time representative of the scintillation crystal. The resulting current produces a measurable electrical pulse; either current or impedance converted voltage may be used to measure the resulting total charge originating in the light sensor. Based on the time coincidence of the electrical pulses and the total energy measurements, three-dimensional images of the measured concentration of the tracer in the subject's body can be produced.

Typical PET systems use block or panel type detectors, each of which use an array of scintillation crystals that are read by an array of photosensors. Both types of detectors use light-sharing techniques to spread the light out from a single scintillator to multiple photosensors. Due to these light-sharing techniques, typical scintillator detectors inherently do not have a uniform light spread pattern. This non-uniformity is also due to the use of a light guide to distribute photons between the scintillator array and the photosensor array. One type of photosensor, a silicon photomultiplier (SiPM) is typically non-linear due to its finite number of microcells which is usually much less than the number of photons impinging on the SiPM. This results in a degrading of the positioning and linearity information of typical PET photosensors such as PMTs and APDs. This non-linearity of the SiPM coupled with the non-uniformity of the scintillator array can produce even more pronounced non-linearity and less efficient light collection in a light-sharing PET detector.

Therefore, a need exists for an improved photosensor design that enables more linear operation and more efficient light collection despite the non-uniform distribution of photons received from the scintillator array.

### BRIEF SUMMARY OF THE INVENTION

Systems, methods, and devices are provided to improve the efficiency of photon detection for nuclear medical imaging.

In one aspect of the invention, a nuclear medical imaging system is provided, including a scintillator array and a photosensor array. The scintillator array is made up of scintillator crystals which emit photons when excited by, for example, gamma radiation, and the emitted photons have a spatial distribution across the photosensor array. The photosensor array includes photosensors for detecting the photons. Each photosensor includes at least one photosensitive microcell, and has a density of photosensitive microcells based at least on the spatial distribution of the photons.

In another aspect of the invention, a block detector for nuclear medical imaging is provided, including a photosensor array, a scintillator array, and a light guide. The scintillator array includes scintillator crystals which emit photons, and the light guide is positioned such that photons received from the scintillator array are distributed to the photosensor array. The photosensor array comprises photosensors for detecting the photons. Each photosensor includes at least one photosensitive microcell, and has a density of photosensitive microcells based at least on a spatial distribution of the photons distributed to the photosensor array.

In yet another aspect of the invention, a method of constructing a photon-detecting photosensor having at least one photosensitive microcell is provided. The method includes the steps of determining a spatial distribution of photons received by the photosensor, and adjusting a density of the photosensitive microcells based at least on the spatial distribution of photons.

Many other aspects and examples will become apparent from the following disclosure.

### BRIEF DESCRIPTION OF THE DRAWINGS

Reference will now be made, by way of example, to the accompanying drawings which show example implementations of the present application.

FIG. 1 illustrates a Positron Emission Tomography (PET) system having fixed detector blocks;

FIG. 2 illustrates an imaging system, e.g., Single Photon Emission Computed Tomography (SPECT) system having detector blocks rotatable about a gantry;

FIG. 3 illustrates a block detector having a plurality of SiPM detectors with microcells of varying densities;

FIG. 4 illustrates the non-linearity caused by non-uniform distribution of light from a scintillator array;

FIG. 5 illustrates the distribution of photons from a scintillator array to a photosensor array for emissions arising from different locations within the scintillator array;

FIG. 6 illustrates exemplary SiPM arrays with varying microcell densities corresponding to the varying photon distributions of scintillator arrays.

FIG. 7 illustrates an exemplary nuclear medical imaging system according to the invention;

FIG. 8 illustrates an exemplary block detector for nuclear medical imaging according to the invention;

FIG. 9 illustrates an exemplary light guide and photosensor array for use in the various embodiments of the invention; and

FIG. 10 illustrates an exemplary photon detection method for nuclear medical imaging according to the invention.

It should be understood that the various embodiments are not limited to the arrangements and instrumentality shown in the drawings.

### DETAILED DESCRIPTION OF THE INVENTION

Reference will now be made in detail to implementations of the technology. Each example is provided by way of explanation of the technology only, not as a limitation of the technology. It will be apparent to those skilled in the art that various modifications and variations can be made in the present technology without departing from the scope or spirit of the technology. For instance, features described as part of one implementation can be used on another implementation to yield a still further implementation. Thus, it is intended that the present technology cover such modifications and variations that come within the scope of the technology.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the term “about” may include numbers that are rounded to the nearest significant figure. Numerical ranges include all values within the range. For example, a range of from 1 to 10 supports, discloses, and includes the range of from 5 to 9. Similarly, a range of at least 10 supports, discloses, and includes the range of at least 15.

Thus, the following disclosure describes systems, methods, and an apparatus for imaging, including a system, a method, and an apparatus for improving the linear and efficiency of output pulses from photosensor arrays such as SiPM arrays. Many other examples and other characteristics will become apparent from the following description.

Medical imaging technology may be used to create images of the human body for clinical purposes (e.g., medical procedures seeking to reveal, diagnose or examine disease) or medical science (including the study of normal anatomy and physiology). Medical imaging technology includes: radiography including x-rays, fluoroscopy, and x-ray computed axial tomography (CAT or CT); magnetic resonance imaging (MRI); and nuclear medical imaging such as scintigraphy using a gamma camera, single photon emission computed tomography (SPECT), and positron emission tomography (PET).

In nuclear medicine imaging, radiopharmaceuticals are taken internally, for example intravenously or orally. Then, external systems capture data from the radiation emitted, directly or indirectly, by the radiopharmaceuticals; and then form images from the data. This process is unlike a diagnostic X-ray where external radiation is passed through the body and captured to form an image.

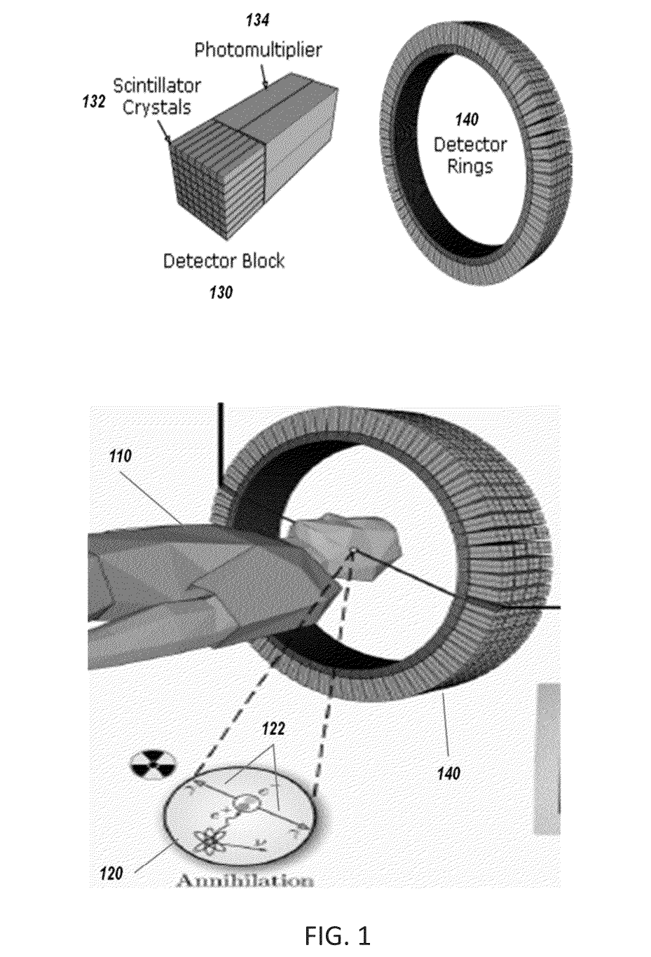

Referring to FIG. 1, in various embodiments of the invention using PET, a short-lived radioactive tracer isotope is injected or ingested into the subject 110. As the radioisotope undergoes positron emission decay 120 (also known as positive beta decay), it emits a positron, an antiparticle of the electron with opposite charge. The emitted positron travels in tissue for a short distance, during which time it loses kinetic energy, until it decelerates to a point where it can interact with an electron. The encounter annihilates both electron and positron, producing a pair of annihilation (gamma) photons 122 moving in approximately opposite directions. These are detected when they reach a scintillator 132 in the scanning device, creating a burst of light which is detected by a photosensor, for example, photomultiplier tubes 134 or silicon avalanche photodiodes (SiAPD). The PET detector blocks 130 are typically fixed in a detector ring 140.

In the various embodiments of the invention, SPECT imaging is performed by using a gamma camera (similar to a PET detector block) to acquire multiple 2-D images (also called projections), from multiple angles. SPECT is similar to PET in its use of radioactive tracer material and detection of gamma rays. In contrast with PET, however, the tracer used in SPECT emits gamma radiation that is measured directly, whereas PET tracer emits positrons which annihilate with electrons up to a few millimeters away, causing two gamma photons to be emitted in opposite directions. A PET scanner detects these emissions “coincident” in time, which provides more radiation event localization information and thus higher resolution images than SPECT. SPECT scans, however, are significantly less expensive than PET scans, in part because they are able to use longer-lived more easily-obtained radioisotopes than PET. Therefore, technology that increases the accuracy of SPECT is desirable.

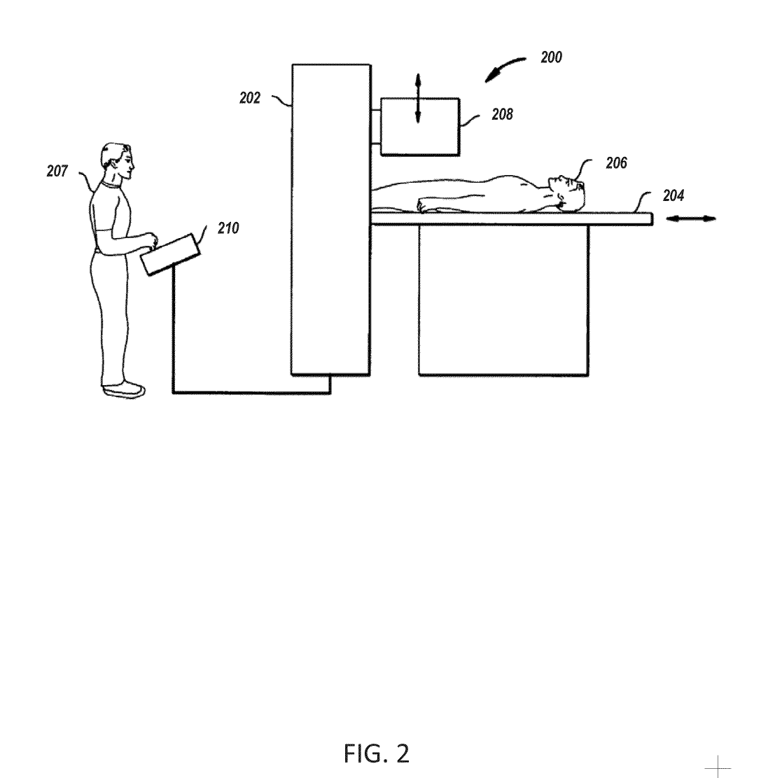

FIG. 2 depicts components of a typical SPECT system 200 used in various embodiments of the invention, which includes a gantry 202 supporting one or more detectors 208 enclosed within a metal housing and movably supported proximate a patient 206 located on a patient support (e.g., pallet or table) 204. In many instances, a data acquisition console 210 (e.g., with a user interface and/or display) is located proximate a patient during use for a technologist 207 to manipulate during data acquisition. In addition to the data acquisition console 210, images are often “reconstructed” or developed from the acquired image data (“projection data”) via a processing computer system that is operated at another image processing computer console including, e.g., an operator interface and a display, which may often be located in another room, to develop images. By way of example, the image acquisition data may, in some instances, be transmitted to the processing computer system after acquisition using the acquisition console.

In the various embodiments of the invention, the photosensor array may be comprised of various types of photosensors, for example, photomultiplier tubes (PMTs), avalanche photodiodes (APDs), or silicon photomultipliers (SiPMs).

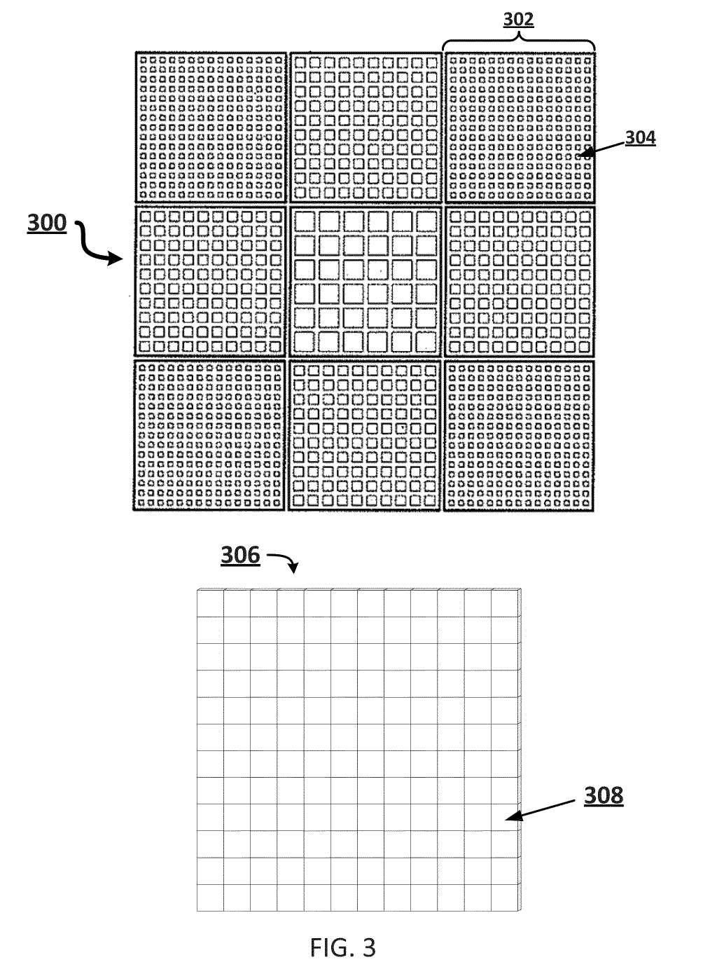

FIG. 3 illustrates an exemplary embodiment of the invention using a photosensor array 300 comprising nine SiPM photosensors 302 arranged in a 3×3 matrix, each photosensor having a density of photosensitive microcells 304 (not drawn to scale) based on the spatial distribution of the emitted photons from a scintillator array 306 having at least one scintillator crystal 308 for emitting photons. The invention is not limited to a specific number or type of photo sensors and thus the use of a 3×3 SiPM photosensor array in this embodiment is merely exemplary.

When designing a SiPM photosensor 302 with a limited number of photosensitive microcells 304, there is usually a trade-off between signal non-linearity and efficiency. Using a larger number of small cells per unit area results in better signal linearity. However, a higher cell density usually also means that the area fill factor is lower and therefore the overall detection efficiency is lower.

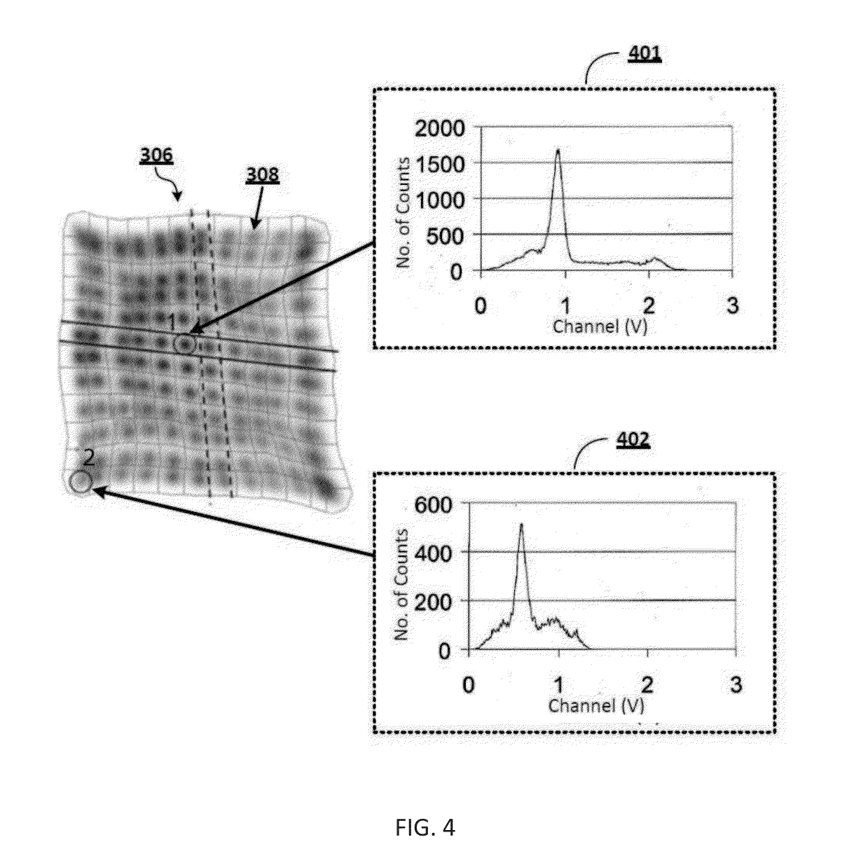

The non-linearity effect can be seen in FIG. 4, which illustrates how the position of the illuminating scintillator crystal 308 within the scintillator array 306 affects the linearity of the energy spectrum readout by a 3×3 photosensor array. The diagram on the left shows the positions of two illumination events within a 12×12 scintillator crystal array 306. Graph 401 depicts the energy spectrum readout by the photosensor array 300 for the light received from central crystal 1, while graph 402 depicts the energy spectrum readout for the light received from corner crystal 2. The energy spectrum depicted in graph 402 shows significant nonlinearity as seen by the compression of the energy scale compared to the energy spectrum depicted in graph 401, which is typical of a linear energy spectrum for ²²Na (an isotope of sodium), which has 2 main gamma energies, 511 keV and 1275 keV. The smoother line of graph 401 illustrates a more linear signal output, where the signal strength increases more consistently relative to the number of additional impinging photons.

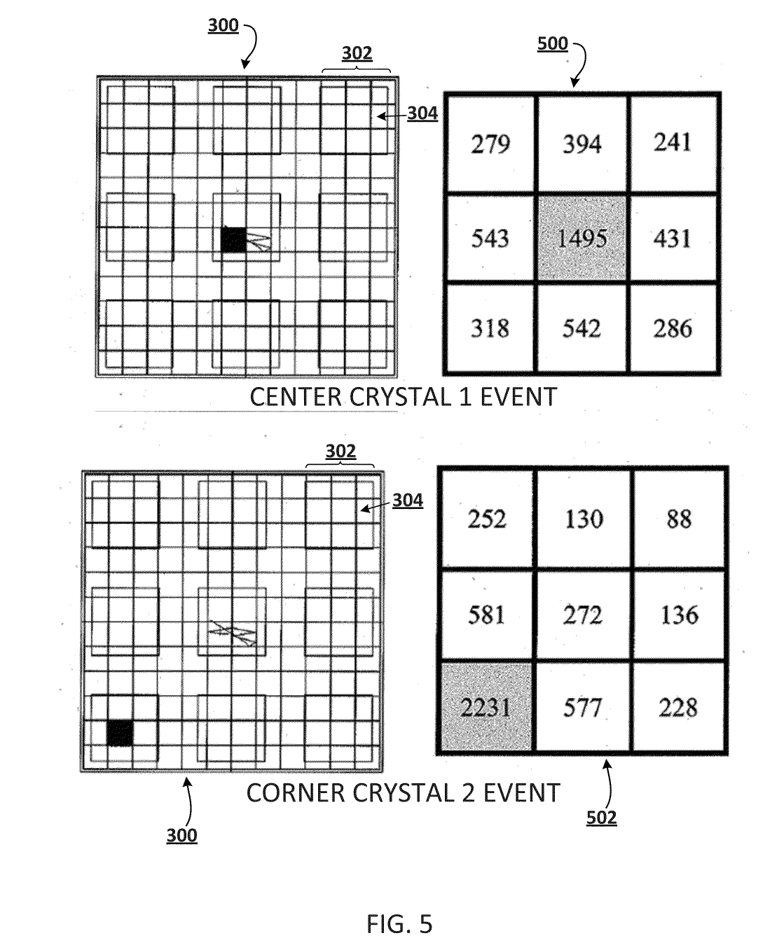

The reason for this non-linearity is that the light from the scintillator array 306 is not distributed uniformly across the photosensor array 300. FIG. 5 compares the spatial distribution of photons across the photosensor array 300 for a central crystal 1 event (illustrated by table 500) to the spatial distribution of photons for a corner crystal 2 event (illustrated by table 502). When a central crystal 1 interaction occurs, the number of photons is more evenly spread across the photosensor array 300 as compared to a corner crystal 2 event. About 50% more photons impinge on a single corner photosensor 302 for a corner crystal 2 event as compared to the light that impinges on the center photosensor 302 for a center crystal 1 event, as illustrated by FIG. 5. A higher proportion of photons would not be detected in the corner crystal 2 event compared to the center crystal 1 event due to the finite number of microcells 304 on the photosensors 302, thus, the energy linearity of the corner crystal 2 would be degraded as compared to the central crystal 1.

In the various embodiments of the invention, however, this degradation of linearity is reduced because each photosensor 302 has a density of photosensitive microcells 304 based at least on the spatial distribution of the photons emitted by the scintillator array 306. For example, the corner photosensors 302 would have a higher density of microcells 304 and/or smaller microcells 304 to more efficiently collect the greater distribution of photons directed at the corner photosensor 302. Whereas conversely, the center photosensor 302 would have a lower density of microcells 304 and/or larger microcells 304, since the light from the central crystal 1 events is distributed more evenly across the photosensor array 300.

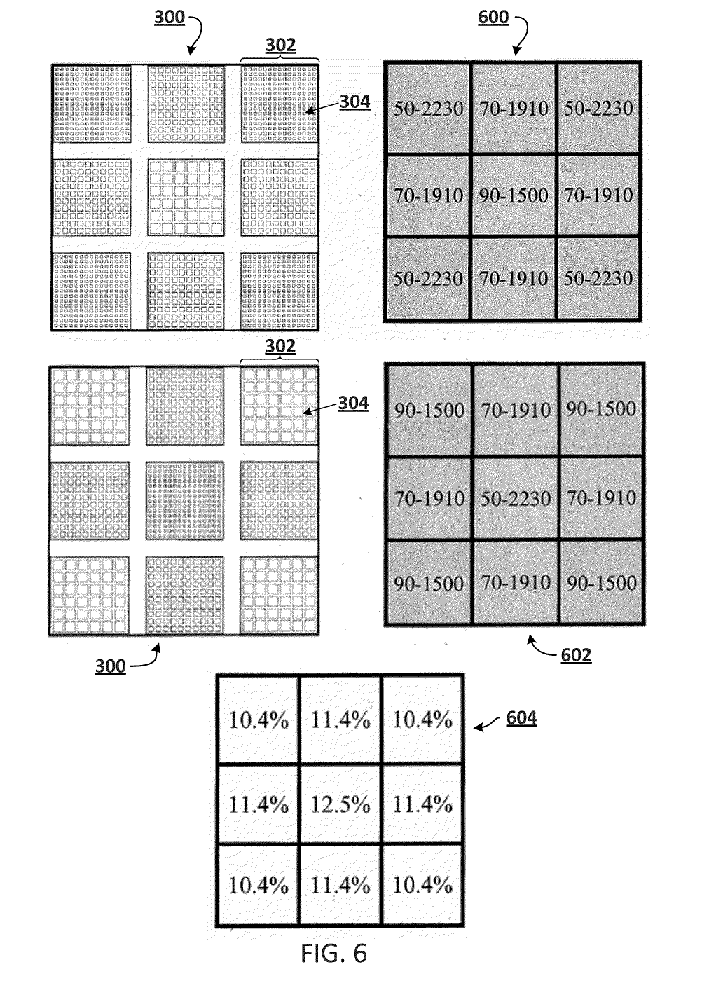

FIG. 6 illustrates exemplary photosensor arrays where the density of photosensitive microcells in each photosensor is based on the spatial distribution of the emitted photons. Each cell of table 600 shows the minimum and maximum number of photons detected by each of the photosensors 302 in a 3×3 photosensor array 300 using the 12×12 scintillator array 306. These values would be proportional to the number of photosensitive microcells 304 that would be needed for each corresponding photosensor 302 to reduce the non-linearity effect. To the left of table 600, photosensor array 300 illustrates an exemplary 3×3 array of photosensors 302 (not to scale), with each photosensor 302 having a different density and size of photosensitive microcells 304, based on the values in table 600 (differences in density are exaggerated for better illustration). The spatial distribution may be different depending on the scintillator array 306, for example, the center photosensor 302 may receive a greater distribution of photons than the surrounding photosensors 302. Table 602 shows the minimum and maximum number of photons detected by each of the photosensors 302 in a 3×3 photosensor array 300 using a different 12×12 scintillator array 306. Again, the values for density of photosensitive microcells 304 in each photosensor 302 are made proportional to the number of photons impinging on the respective photosensors 302, as illustrated by exemplary photosensor array 300 to the left of table 602 (not to scale, differences in density exaggerated for better illustration). The values for density of photosensitive microcells 304 in each photosensor 302 can also be based on different values, for example, the percentage of photons detected by each photosensor 302, averaged over all of the scintillator crystals 308, as illustrated by table 604. The value could also be an average number of photons detected by each photosensor 302, averaged over all of the scintillator crystals 308, rather than a maximum or minimum number of photons detected. These possible values are provided as non-limiting examples, and other values will be readily apparent to an ordinary person skilled in the art.

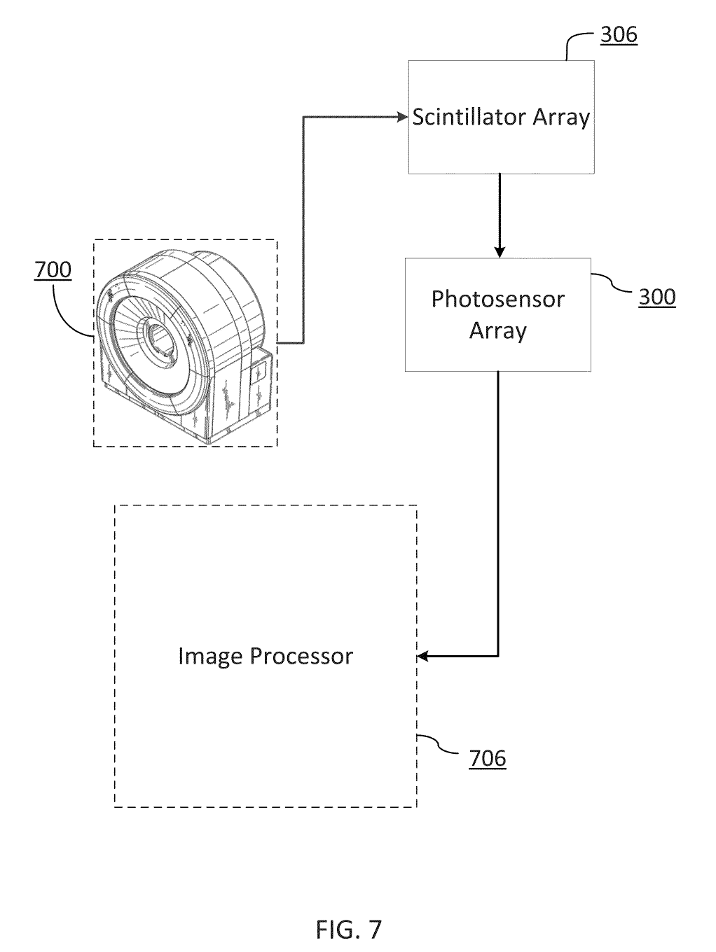

FIG. 7 illustrates an exemplary embodiment of a nuclear medical imaging system according to the invention. Positron annihilations occur within a tracer substance in the item of interest placed in scanner 700, for example, a patient in a PET scanner bed, and the resulting gamma photons excite scintillator crystals 308 within the scintillator array 306. As a result, the scintillator crystals comprising the scintillator array 306 emit light photons, which are received by the photosensors 302 comprising the photosensor array 300. The emitted light photons have a spatial distribution based on the arrangement of scintillator crystals 308 within the scintillator array 306, among other factors. The photosensors 302 comprising the photosensor array 300 each have a density of photosensitive microcells 304 based in part on this spatial distribution of the emitted photons. The photosensor 302 may convert the received photons into a measurable electrical pulse having a magnitude proportional to the number of photons received, which it outputs to an image processor 706. Image processor 706 may use the time coincidence of electrical pulses from opposing pairs of photosensors, and the total energy measurements, to acquire imaging data representative of an image of anatomical function of organs and tissues of a patient, for example. The acquired imaging data is then reconstructed using specific reconstruction algorithms to generate three-dimensional images of the measured concentration of the tracer substance in the patient's body.

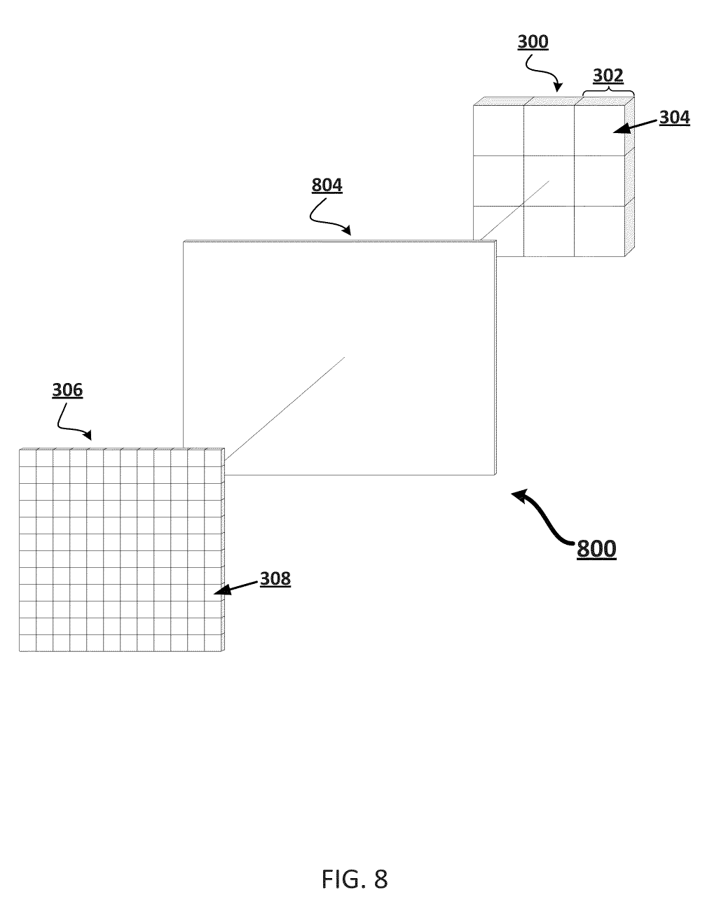

FIG. 8 illustrates an exemplary embodiment of a block detector for nuclear medical imaging, according to the invention. Block detector 800 may be used in various imaging systems such as PET and/or SPECT applications. Detector 800 includes a scintillator array 306 comprising 144 Lutetium Oxyorthosilicate (LSO) scintillator crystals 308 for emitting photons, arranged in a 12×12 matrix. Detector 800 also includes a light guide 804 positioned such that light received from the scintillator array 306 is distributed to the photosensor array 300. Photosensor array 300 comprises nine SiPM photosensors 302, each photosensor 302 comprising a plurality of photosensitive microcells 304. The density of photosensitive microcells 304 in each photosensor 302 is based on the spatial distribution of the light distributed from the scintillator array 306, through the light guide 804, across the photosensor array 300. For example, the density of photosensitive microcells 304 in corner photosensor 302 is proportional to the number of photons impinging on photosensor 302 from the scintillator array 306, which in turn is based on the geometry of the LSO scintillator to which the photosensor array 300 is coupled. Similarly, each other photosensor in photosensor array 300 will have a photosensitive microcell 304 density configured to correspond to the spatial distribution of photons across it, as determined from the measurements reflected in FIGS. 5 and 6. This results in a more linear and efficient output pulse from the photosensor array 300.

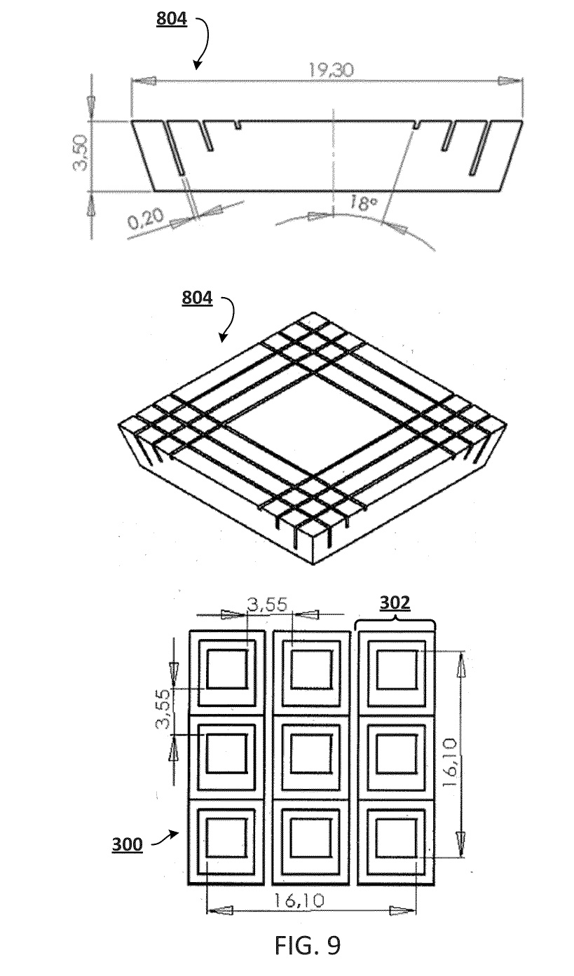

FIG. 9 illustrates an exemplary light guide and photosensor array 300 used in the various embodiments of the invention. The top depiction in FIG. 9 illustrates a schematic view of an exemplary light guide 804, with dimensions in millimeters. The central depiction in FIG. 9 depicts exemplary light guide 804 in a 3-dimensional view. As illustrated, the light guide 804 may have channels of varying depth and angle cut into it so as to guide light in a desired direction from the incident side of the light guide to its output side. For example, the tapered channels can be used to spread light evenly over the surface of the coupled photosensor. The lower depiction in FIG. 9 depicts an exemplary photosensor array 300, with dimensions in millimeters. The photosensor array 300 comprises nine SiPM photosensors 302 arranged in a 3×3 matrix. Each photosensor 302 has a plurality of microcells.

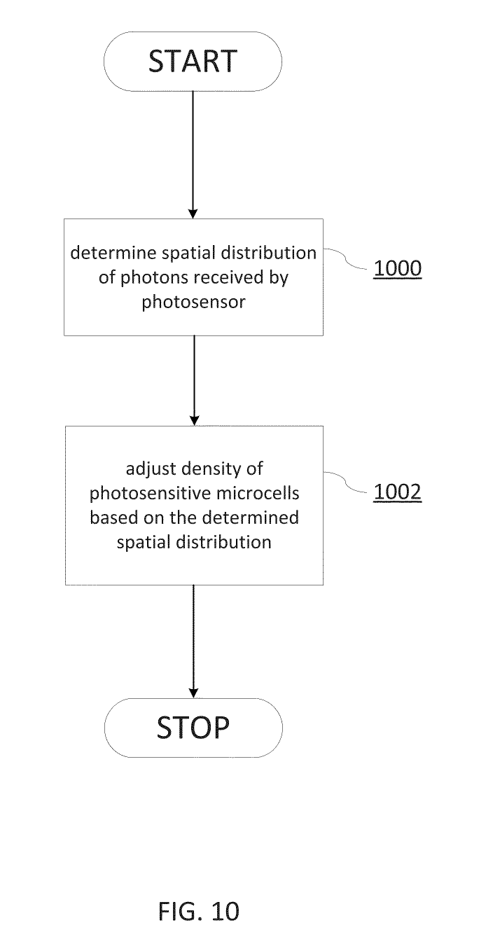

FIG. 10 is a flowchart illustrating an exemplary method of constructing a photon-detecting photosensor 302 having at least one photosensitive microcell 304. In step 1000, a spatial distribution of photons received by the photosensor in accordance with its particular geometry with respect to an associated scintillator is determined. In step 1002, a density of the photosensitive microcells is adjusted based on the determined spatial distribution of photons. For example, the more photons that are received by the photosensor 302, the greater the density of photosensitive microcells 304 will be. The density of photosensitive microcells can be, for example, directly proportional to the number of photons received. The value of the number of photons received may be, for example, a maximum or minimum number of photons received by the photosensor, or an average number of photons received by the photosensor, or a percentage of photons received by the photosensor. These values are presented as non-limiting examples, and other possible values will be readily apparent to a person of ordinary skill in the art.

What is claimed is:

1. A nuclear medical imaging system comprising:
a scintillator array comprising at least one scintillator crystal for emitting photons in response to incident nuclear radiation, the emitted photons having a spatial distribution profile across the scintillator; and
a photosensor array comprising at least two photosensors for detecting the emitted photons, each photosensor comprising a plurality of photosensitive microcells, wherein each photosensor has a density of photosensitive microcells that is determined based at least on the spatial distribution of the photons.

2. The imaging system of claim 1, wherein the photosensor array is a silicon photomultiplier (SiPM) array.

3. The imaging system of claim 1, wherein the density of photosensitive microcells of each photosensor is proportional to a number of photons received by the photosensor.

4. The imaging system of claim 3, wherein the number of photons is an average number of photons received by the photosensor.

5. The imaging system of claim 3, wherein the number of photons is a maximum number of photons received by the photosensor.

6. The imaging system of claim 1, wherein the density of photosensitive microcells of each photosensor is proportional to a percentage of photons received by the photosensor.

7. The imaging system of claim 1, each photosensor comprising photosensitive microcells of the same size.

8. The imaging system of claim 1, wherein the photosensitive microcells of one photosensor has a size, the size being different from the size of the photosensitive microcells of at least one other photosensor.

9. The imaging system of claim 1, wherein the imaging system is one of a positron emission tomography (PET) system or a single photon emission computed tomography (SPECT) system.

10. A block detector for nuclear medical imaging, comprising:
a photosensor array comprising at least two photosensors, each photosensor comprising a plurality of photosensitive microcells;
a scintillator array comprising at least one scintillator crystal for emitting photons in response to incident nuclear radiation; and
a light guide positioned such that photons received from the scintillator array are distributed to the photosensor array;
wherein each photosensor has a density of photosensitive microcells that is determined based at least on a spatial distribution profile of the photons distributed to the photosensor array.

11. The block detector of claim 10, wherein the photosensor array is a silicon photomultiplier (SiPM) array.

12. The block detector of claim 10, wherein the density of photosensitive microcells of each photosensor is proportional to a number of photons received by the photosensor.

13. The block detector of claim 12, wherein the number of photons is an average number of photons received by the photosensor.

14. The block detector of claim 12, wherein the number of photons is a maximum number of photons received by the photosensor.

15. The block detector of claim 10, wherein the density of photosensitive microcells of each photosensor is proportional to a percentage of photons received by the photosensor.

16. A method of constructing a photon-detecting photosensor having a plurality of photosensitive microcells, the method comprising:
determining a spatial distribution of photons received by the photosensor according to an intended geometry of said photosensor with respect to an associated scintillator that emits photons in response to incident nuclear radiation;
determining a density of the photosensitive microcells based at least on the spatial distribution of photons of said scintillator and the intended geometry of said photosensor with respect to said spatial distribution; and
manufacturing said photon-detecting photosensor to have said determined density.

17. The method of claim 16, wherein the photosensor is a silicon photomultiplier (SiPM).

18. The method of claim 16, wherein the density of photosensitive microcells is proportional to a number of photons received by the photosensor as compared with a number of photons received by another photosensor in an array of which the photosensors are members.

19. The method of claim 18, wherein the number of photons is an average number of photons received by the photosensor.

20. The method of claim 18, wherein the number of photons is a maximum number of photons received by the photosensor.
